(19) United States
(12) Patent Application Publication
(10) Pub. No.: US 2026/0229876 A1
(43) Pub. Date: Aug. 6, 2026

(54) BATTERY DISCONNECT UNIT

(71) Applicant: Panasonic Intellectual Property Management Co., Ltd., Osaka (JP)

(72) Inventors: Hideki IWAKI, Osaka (JP); Eiichi SADAYUKI, Osaka (JP); Tomoaki FURUSE, Osaka (JP); Takashi MONDEN, Kyoto (JP); Koji YOSHINO, Kanagawa (JP); Jo YAMAKAWA, Osaka (JP)

(73) Assignee: Panasonic Intellectual Property Management Co., Ltd., Osaka (JP)

(21) Appl. No.: 19/150,590

(22) PCT Filed: Jan. 19, 2024
(86) PCT No.: PCT/JP2024/001461

§ 371 Date: Jul. 24, 2025

(30) Foreign Application Priority Data
Feb. 2, 2023 (JP) 2023-014678

(51) Int. Cl. H02H 7/18; B60L 3/04; B60L 50/60; B60L 58/10; G01R 19/165; H02H 1/00

(52) U.S. Cl. CPC H02H 7/18; B60L 3/04; B60L 58/10; G01R 19/16571; H02H 1/0007; B60L 50/60

(57) ABSTRACT

A battery disconnect unit for use in transportation equipment including a battery and a load includes a pyrofuse, a mechanical relay including a first contact and a second contact, a current sensor, and a disconnection control circuit connected to the current sensor and the pyrofuse. The current sensor outputs a current value of a current flowing in a current path between the battery and the load, to the disconnection control circuit. The disconnection control circuit outputs an ignition signal to the pyrofuse based on the current value. The pyrofuse disconnects the current path by the ignition signal, and the mechanical relay is turned on and off by a control signal from outside of the battery disconnect unit.

### TECHNICAL FIELD

The present disclosure relates to a battery disconnect unit for use in transportation equipment.

### BACKGROUND ART

Patent Literature (PTL) 1 discloses a system which causes a fuse to disconnect a current path based on a current value detected by a current sensor.

### CITATION LIST

### Patent Literature

[PTL 1] Japanese Unexamined Patent Application Publication No. 2015-91199

### SUMMARY OF INVENTION

### Technical Problem

The system disclosed in PTL 1 above may not disconnect the current path safely in transportation equipment including a battery of a large capacity, such as electric vehicles.

Thus, the present disclosure provides a battery disconnect unit which enables safe disconnection of a current path in transportation equipment including a battery of a large capacity.

### Solution to Problem

The battery disconnect unit according to one aspect of the present disclosure is a battery disconnect unit for use in transportation equipment including a battery and a load, the battery disconnect unit including: a pyrofuse; a mechanical relay including a first contact and a second contact; a current sensor; and a disconnection control circuit connected to the current sensor and the pyrofuse. Here, the current sensor outputs, to the disconnection control circuit, a current value of a current flowing in a current path between the battery and the load, the disconnection control circuit outputs an ignition signal to the pyrofuse based on the current value, the pyrofuse disconnects the current path by the ignition signal, and the mechanical relay is turned on and off by a control signal from outside of the battery disconnect unit.

These general or specific aspects may be implemented by a system, a method, an integrated circuit, a computer program, or a recording medium such as a computer-readable CD-ROM, or may be implemented by any combination of systems, methods, integrated circuits, computer programs, and recording media.

### Advantageous Effects of Invention

The battery disconnect unit according to one aspect of the present disclosure enables safe disconnection of a current path in transportation equipment including a battery of a large capacity.

### BRIEF DESCRIPTION OF DRAWINGS

FIG. 1 is an appearance diagram illustrating one example of a battery disconnect unit according to an embodiment.

FIG. 2 is a block diagram illustrating one example of the battery disconnect unit according to the embodiment.

FIG. 3 is a cross-sectional view illustrating one example of a pyrofuse according to the embodiment.

FIG. 4 is a diagram illustrating current voltage characteristics of the battery disconnect unit according to the embodiment.

FIG. 5 is a side view illustrating one example of a mechanical relay according to the embodiment.

### DESCRIPTION OF EMBODIMENTS

Hereinafter, an embodiment will be specifically described with reference to the drawings.

An embodiment described below all illustrates general or specific examples. Numeric values, shapes, materials, components, arrangement positions of components and connection forms thereof, steps, order of steps, and the like shown in an embodiment below are exemplary, and should not be construed as limitations to the present disclosure.

### Embodiment

Hereinafter, a battery disconnect unit according to an embodiment will be described.

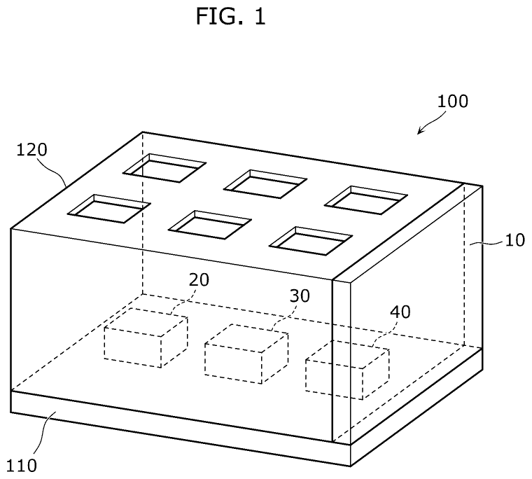

FIG. 1 is an appearance diagram illustrating one example of battery disconnect unit 100 according to an embodiment. In the appearance diagram illustrated in FIG. 1, terminals and wirings are omitted, and components are schematically illustrated as a cuboid shape or the like.

Battery disconnect unit 100 includes pyrofuse (ignition-type disconnection device) 20, mechanical relay 30, current sensor 40, disconnection control circuit 10, and one rigid body portion 110.

Rigid body portion 110 fixes pyrofuse 20, mechanical relay 30, current sensor 40, and disconnection control circuit 10. For example, rigid body portion 110 is a base on which pyrofuse 20, mechanical relay 30, current sensor 40, and disconnection control circuit 10 are mounted. Rigid body portion 110 may be a metal plate, and may dissipate heat as a heat sink. For example, parts other than parts related with pyrofuse 20, mechanical relay 30, current sensor 40, and disconnection control circuit 10 are not fixed to rigid body portion 110.

For example, disconnection control circuit 10 is formed on a substrate or the like, and in the example illustrated in FIG. 1, the substrate forming disconnection control circuit 10 is vertically fixed at one end of rigid body portion 110.

For example, battery disconnect unit 100 includes cover 120, and pyrofuse 20, mechanical relay 30, and current sensor 40 are covered with cover 120. For example, as illustrated in FIG. 1, cover 120 may not cover disconnection control circuit 10, and disconnection control circuit 10 may form a wall of battery disconnect unit 100. In battery disconnect unit 100 illustrated in FIG. 1, pyrofuse 20, mechanical relay 30, and current sensor 40 are covered with the substrate forming disconnection control circuit 10 and cover 120. For example, holes may be disposed on the top surface of cover 120 as illustrated in FIG. 1. These holes can enhance heat dissipating properties. For example, cover 120 may be formed from a resin.

Thus, battery disconnect unit 100 is a single unit including one rigid body portion 110 in the center thereof. Rigid body portion 110 may be a housing which covers and fixes pyrofuse 20, mechanical relay 30, current sensor 40, and disconnection control circuit 10.

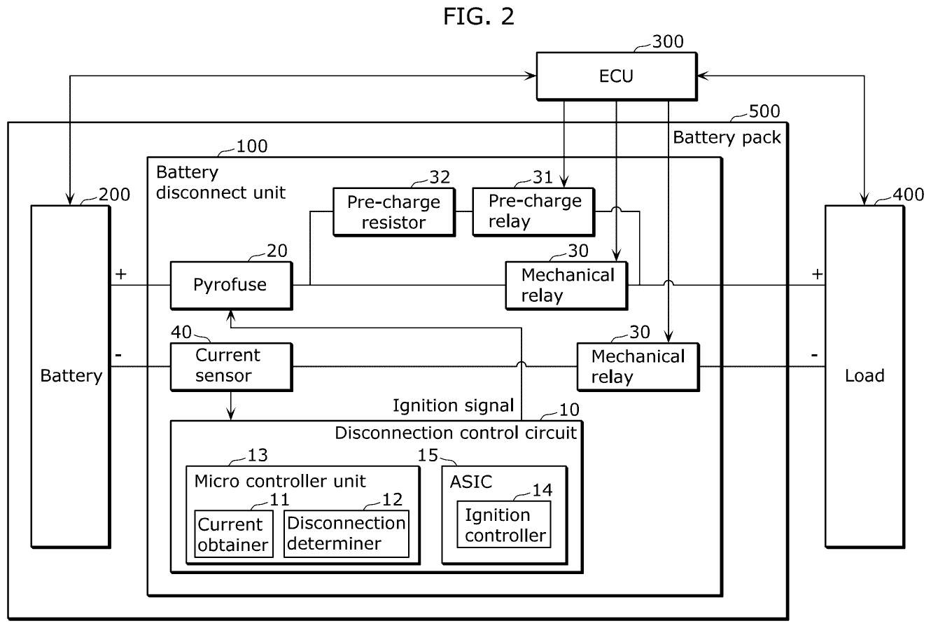

FIG. 2 is a block diagram illustrating one example of battery disconnect unit 100 according to the embodiment. Battery disconnect unit 100 is included in transportation equipment including electronic control unit (ECU) 300, battery 200, and load 400. FIG. 2 also illustrates battery 200 included in transportation equipment, battery pack 500 covering battery 200, ECU 300, and load 400 as well as battery disconnect unit 100. As illustrated in FIG. 2, battery 200, ECU 300, and load 400 are arranged outside battery disconnect unit 100. In FIG. 2, lines connecting battery 200 and load 400 represent the flows of current (electricity), and arrows represent the flows of signals. ECU 300 is connected to battery 200 and load 400 but not to current sensor 40, and outputs a control signal. Battery disconnect unit 100 is used in an electric vehicle, for example, as transportation equipment.

Battery 200 is, for example, a battery which can apply high voltage to load 400. For example, battery 200 is a main battery (such as a lithium ion battery) in an electric vehicle, and is not a sub battery used in transportation equipment equipped with a gasoline engine, such as a lead-acid battery. Battery 200 is covered with battery pack 500.

For example, load 400 is a motor and inverter of an electric vehicle. Electricity is fed from battery 200 to load 400 to propel and drive the electric vehicle. When an accident occurs, a large current flows due to short-circuit abnormality in a current path connected to battery 200 and load 400, and battery 200 may smoke or ignite. For this reason, battery disconnect unit 100 is used in transportation equipment.

ECU 300 is a device for controlling battery 200, load 400 and other various components (such as steering, a variety of sensors, communication devices, and In Vehicle Infotainment (IVI)) included in the transportation equipment. Although one ECU 300 is illustrated herein, ECU 300 may be configured with a plurality of ECUs. For example, ECU 300 is connected to battery 200, and can transmit and receive signals to and from battery 200 to monitor the state of battery 200. For example, ECU 300 is connected to load 400, and can transmit and receive signals to and from load 400 to monitor the state of load 400. For example, ECU 300 controls mechanical relay 30 and the like included in battery disconnect unit 100. In other words, mechanical relay 30 is turned on and off by a control signal from outside of battery disconnect unit 100 (specifically, control signal from ECU 300). For example, mechanical relay 30 is turned on and off by a control signal based on information from battery 200 or load 400, which is obtained by ECU 300.

Battery disconnect unit 100 is a unit for disconnecting the current path connecting battery 200 and load 400. The current path connecting battery 200 and load 400 may be a path connecting the plus terminal of battery 200 to the plus terminal of load 400, or may be a path connecting the minus terminal of battery 200 to the minus terminal of load 400. The disconnection of the current path includes a case where the current path is disconnected by disconnecting the wiring through which the current flows (e.g., a busbar), and a case where the current path is disconnected by turning off a relay which is interposed in the current path to configure part of the current path.

Battery disconnect unit 100 includes disconnection control circuit 10, pyrofuse 20, mechanical relay 30, pre-charge relay 31, pre-charge resistor 32, and current sensor 40. As illustrated in FIG. 2, battery disconnect unit 100 may include a plurality of mechanical relays 30. For example, battery disconnect unit 100 with battery 200 is covered with battery pack 500. Battery disconnect unit 100 may be disposed separately from battery pack 500.

Disconnection control circuit 10 is connected to current sensor 40 and pyrofuse 20. Current sensor 40 outputs, to disconnection control circuit 10, the current value of the current flowing in the current path between battery 200 and load 400. Disconnection control circuit 10 outputs an ignition signal to pyrofuse 20 based on the current value, and pyrofuse 20 disconnects the current path by the ignition signal.

For example, disconnection control circuit 10 may recognize occurrence of arc discharge in mechanical relay 30, based on a change in the current value from current sensor 40, and may output the ignition signal to pyrofuse 20.

For example, disconnection control circuit 10 may store a first time period that is from the output of the ignition signal to the occurrence of arc discharge in pyrofuse 20, may predict a time when the current value of the current flowing in the current path exceeds a threshold current, using the first time period and a plurality of current values that are measured at different measurement times and input from current sensor 40, and may output the ignition signal to pyrofuse 20 based on the prediction, to cause arc discharge to occur in mechanical relay 30 and then in pyrofuse 20 and to cause a period during which arc discharge occurs in mechanical relay 30 and a period during which arc discharge occurs in pyrofuse 20 to overlap with each other.

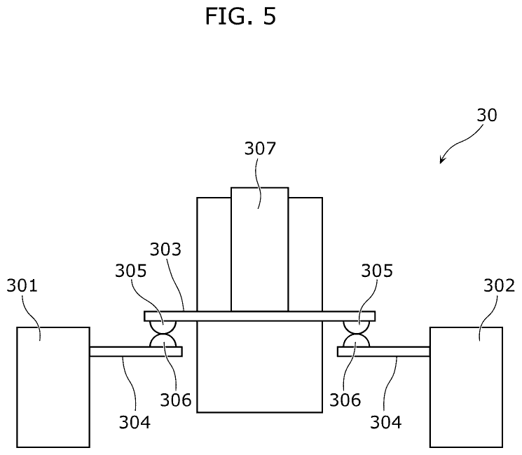

For example, when a current exceeding the threshold current flows in the current path (including a case where a current exceeding the threshold current actually flows in the current path and a case where it is predicted that a current exceeding the threshold current flows in the current path), after contact 305 included in mechanical relay 30 (see FIG. 5 described later) is spaced from contact 306 (see FIG. 5 described later) and arc discharge occurs, disconnection control circuit 10 outputs an ignition signal to pyrofuse 20 to disconnect load 400 and battery 200. Thus, arc discharge occurs both between the first contact and the second contact and in the portion of the current path decoupled by pyrofuse 20.

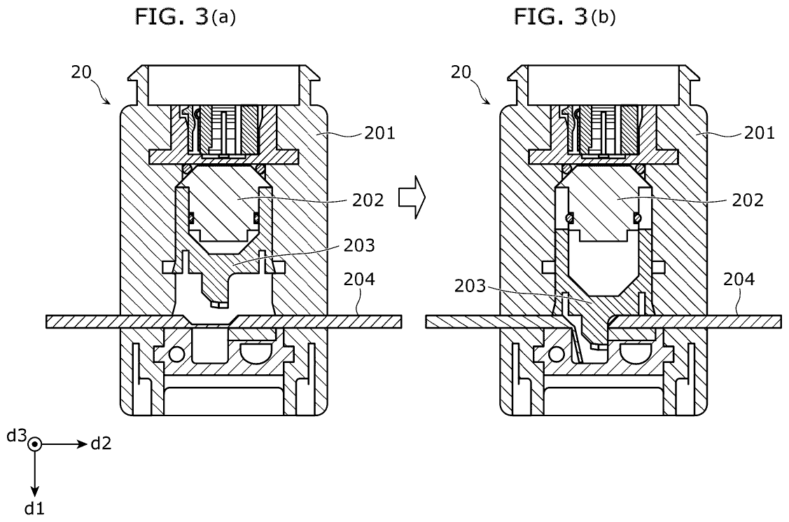

FIG. 3 is a cross-sectional view illustrating one example of pyrofuse 20 according to an embodiment. (a) of FIG. 3 illustrates the state before disconnection of busbar 204 configuring the current path, and (b) of FIG. 3 illustrates the state after disconnection of busbar 204. Pyrofuse 20 illustrated in FIG. 3 is only one example.

As illustrated in (a) of FIG. 3, pyrofuse 20 includes casing 201 forming an outer shell of pyrofuse 20, piston 203 movable in first direction d1, igniter 202 that actuates piston 203, and busbar 204 interposed in the current path to form part of the current path.

Casing 201 has a tubular shape, and is disposed along first direction d1. Inside casing 201, the central portion of busbar 204, piston 203, and igniter 202 are arranged. Both ends of busbar 204 are arranged outside casing 201. Busbar 204 is a straight and plate-like conductor, and is disposed along second direction d2 intersecting first direction d1. In this example, second direction d2 is a direction vertical to first direction d1. Busbar 204 extending in second direction d2 penetrates through the lateral surface of casing 201, and both ends of busbar 204 project from the lateral surface of casing 201 to the outside thereof.

As illustrated in (a) of FIG. 3, igniter 202 is disposed inside casing 201. When an overcurrent occurs, namely, when the ignition signal output from disconnection control circuit 10 is accepted, igniter 202 actuates piston 203. Specifically, igniter 202 ignites gunpowder to rapidly expand the gas inside casing 201, thereby moving piston 203 in first direction d1 at a high speed.

Piston 203 has a cylindrical shape, and is disposed inside casing 201 along first direction d1. Piston 203 moves in first direction d1 as a result of ignition by igniter 202 to disconnect busbar 204 (see (b) of FIG. 3). When piston 203 decouples busbar 204, piston 203 collides against part of busbar 204 or casing 201 to generate vibration in first direction d1.

Pyrofuse 20 is a fuse for cutting off the current path connecting battery 200 and load 400 when a large current caused by short-circuit abnormality flows in the current path. Pyrofuse 20 contains gunpowder, and ignites the gunpowder based on a signal from outside of pyrofuse 20 to irreversibly cut off the current path with explosion power caused by the ignition of the gunpowder and thus disconnect the current path. Pyrofuse 20 disconnects the current path by the ignition signal from disconnection control circuit 10. For example, pyrofuse 20 is disposed in the current path connecting the plus terminal of battery 200 to the plus terminal of load 400, and disconnects the current path by ignition signal from disconnection control circuit 10.

For example, pyrofuse 20 is capable of continuously electrically conducting a current of 500 A or less, and is capable of electrically conducting a current of about 1200 A for a few seconds to dozen seconds. For example, pyrofuse 20 is capable of disconnecting the current path in which a current of 16000 A to 25000 A flows under application of a voltage of 500 V to 1000 V. In pyrofuse 20, the conducting path (current path) is isolated from the ignition signal path, so that a high voltage is not applied to the ignition signal path.

Next, details of a timing at which disconnection control circuit 10 transmits the ignition signal to pyrofuse 20 will be described. Although mechanical relay 30 will be described below as an example, pre-charge relay 31 can also be operated likewise.

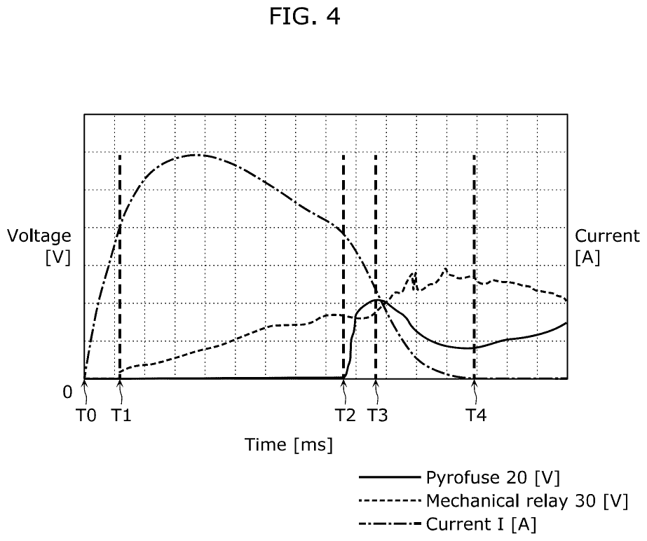

FIG. 4 is a diagram illustrating current voltage characteristics of battery disconnect unit 100 according to the embodiment of the present disclosure, and a diagram illustrating a change in the current monitored by current sensor 40.

The current value monitored by current sensor 40 is transmitted to disconnection control circuit 10. At time TO, current I starts rising, and at time T1, it reaches a current value larger than the short-circuit withstand time current (threshold current) of mechanical relay 30, and an overcurrent flows. Then, contact 305 and contact 306 are spaced from each other, and arc discharge occurs between contact 305 and contact 306 (voltage of mechanical relay 30 rises at time T1 in FIG. 4).

Time T1 is a timing at which arc discharge starts in mechanical relay 30. At this time, the current path is not disconnected by pyrofuse 20, and arc discharge does not occur in pyrofuse 20. ECU 300 may transmit a disconnection signal (OFF signal) to mechanical relay 30 at a timing before or after time T1.

Next, in the period from time T1 to time T2, arc discharge occurs between contact 305 and contact 306, and current I also rises after it exceeds the short-circuit withstand time current (threshold current), followed by a reduction in current value.

Next, at a timing of time T2 (before or after time T2), disconnection control circuit 10 transmits the ignition signal to pyrofuse 20 based on the current value (monitoring current information) from current sensor 40. Thereby, pyrofuse 20 decouples the current path, and arc discharge also occurs in the portion of the current path decoupled by pyrofuse 20 (at time T2 in FIG. 4, voltage of the pyrofuse 20 (voltage of the disconnected portion) rises).

Next, from time T2 to time T3, arc discharge occurs both of mechanical relay 30 (specifically, between contact 305 and contact 306) and pyrofuse 20 (specifically, in the portion of the current path decoupled by pyrofuse 20).

In the period from time T2 to time T3, the current value reduces as in the period from time T1 to time T2. However, the current value reduction rate in the period from time T2 to time T3 is greater than that in the period from time T1 to time T2.

In other words, using the current value (monitoring current information) from current sensor 40, disconnection control circuit 10 transmits the ignition signal to pyrofuse 20 from current sensor 40 at a timing of time T2 (or period from time T2 to time T3), based on the current value (current information).

When disconnection control circuit 10 determines to output the ignition signal, as one example, disconnection control circuit 10 stores the time period that is from output of the ignition signal to occurrence of arc discharge in pyrofuse 20 (referred to as first time period), predicts the time when the current value exceeds the short-circuit withstand time current (threshold current) using the first time period and a plurality of current values (current information) measured at different times (referred to as measurement time) and input from current sensor 40, and outputs the ignition signal to pyrofuse 20 based on the prediction, to cause arc discharge to occur in mechanical relay 30 and then in pyrofuse 20 and to cause the period during which arc discharge occurs in mechanical relay 30 and the period during which arc discharge occurs in pyrofuse 20 to overlap with each other.

Disconnection control circuit 10 can determine the timing to transmit the ignition signal to pyrofuse 20 using another method. For example, disconnection control circuit 10 may perform the determination at a timing (timing of time T2 in FIG. 4) at which disconnection control circuit 10 recognizes that the current value increases to exceed the short-circuit withstand time current (threshold current), and further increases to reach a maximum value after a while, and subsequently, reduces, resulting in a change in the current reduction rate, and disconnection control circuit 10 may transmit the ignition signal to pyrofuse 20 at this timing.

Furthermore, as another example, a timing at which disconnection control circuit 10 recognizes that the current value increases to exceed the short-circuit withstand time current (threshold current), reaches a maximum value after a while, and subsequently, reduces to reach a current value lower than a predetermined value (reference value for determining disconnection) may be selected as the timing to transmit the ignition signal to pyrofuse 20.

In other words, because disconnection control circuit 10 can recognize occurrence of arc discharge in mechanical relay 30 by monitoring the change in the current value, disconnection control circuit 10 can output the ignition signal to pyrofuse 20 based on the change in the current value from current sensor 40.

Next, pyrofuse 20 receives the ignition signal, and disconnects the current path. This increases a difference in potential between one end of the current path and the other end thereof. Subsequently, this difference in potential rapidly beings to decrease, and current I rapidly begins to decrease at time T3. Subsequently, at time T4, the current flowing between battery 200 and load 400 is completely disconnected.

As described above, in battery disconnect unit 100 according to the present embodiment, disconnection instructions to mechanical relay 30 and pyrofuse 20 are transmitted by separate circuits (specifically ECU 300 and disconnection control circuit 10) as a feature.

In other words, ECU 300 provided in the transportation equipment gives a signal to mechanical relay 30, and thereby mechanical relay 30 is turned off. For example, when a variety of failures in the transportation equipment excluding failures such as flowing of an overcurrent occur, mechanical relay 30 is turned off. Thereby, battery disconnect unit 100 can disconnect (turn on and off) the current path several times (repeatedly) by mechanical relay 30.

On the other hand, when an overcurrent occurs, battery disconnect unit 100 according to the present embodiment can disconnect pyrofuse 20 in response to the ignition signal from disconnection control circuit 10 based on the current value (monitoring current information) from current sensor 40.

In other words, battery disconnect unit 100 can appropriately perform disconnection in a variety of situations by giving a signal to mechanical relay 30 from ECU 300 of the transportation equipment (from outside of battery disconnect unit 100) and by giving a signal to pyrofuse 20 from disconnection control circuit 10 inside battery disconnect unit 100.

In battery disconnect unit 100 according to the present embodiment, disconnection control circuit 10 included in battery disconnect unit 100 is not connected to ECU 300 provided in the outside of battery disconnect unit 100, and disconnection control circuit 10 and ECU 300 need not to share information and the like (share determinations). Current sensor 40 included in battery disconnect unit 100 is not connected to ECU 300 provided in the outside of battery disconnect unit 100, and ECU 300 need not to recognize the current value (current information) from current sensor 40. In other words, irrespective of whether the current exceeds the overcurrent or not, battery disconnect unit 100 according to the present embodiment can appropriately perform disconnection using mechanical relay 30 and pyrofuse 20.

Pyrofuse 20 rather than a blown fuse is used in battery disconnect unit 100 because the blown fuse is difficult to satisfy the reaction time and durability at the same time while pyrofuse 20 can satisfy these requirements at the same time.

FIG. 5 is a side view illustrating one example of mechanical relay 30 according to the embodiment. As illustrated in FIG. 5, mechanical relay 30 includes first circuit portion 301, second circuit portion 302, movable terminal 303, fixed terminal 304, contact 305, contact 306, and movable portion 307, and controls movable terminal 303 and fixed terminal 304 to bring these in contact with each other or space these from each other in order to electrically connect or disconnect first circuit portion 301 to or from second circuit portion 302. Contact 305 is one example of the first contact, and contact 306 is one example of the second contact. More preferably, pre-charge relay 31 also has the configuration illustrated in FIG. 5.

Mechanical relay 30 is also a switch for switching on and off the electricity fed from battery 200 to load 400. Mechanical relay 30 is turned on and off by a control signal from ECU 300. For example, when the transportation equipment is activated, mechanical relay 30 is turned on by the control signal from ECU 300, and feed of the electricity to load 400 is started. Mechanical relay 30 is turned off by the control signal from ECU 300.

For example, the control signal from ECU 300 to mechanical relay 30 may be a signal generated based on a result of failure detection in the transportation equipment. For example, ECU 300 detects a failure in the transportation equipment. For example, the failure in the transportation equipment is a failure outside battery disconnect unit 100. For example, the failure in the transportation equipment is a failure other than failures such as flowing of an overcurrent in the current path (such as a failure of battery 200 or load 400). For example, when mechanical relay 30 is in the on state and feed of electricity to load 400 is continued even after output of battery 200 is turned off (including the case where the driver turns off by an operation of the start button), ECU 300 detects the failure in the transportation equipment, generates a control signal for turning off mechanical relay 30, and outputs the control signal to mechanical relay 30. This enables mechanical relay 30 to disconnect the current path in the transportation equipment in which the failure other than failures such as flowing of an overcurrent in the current path occurs.

Thus, ECU 300 that can monitor a variety of states of the transportation equipment such as the states of battery 200 and load 400 can disconnect the current path by turning off mechanical relay 30 for the failures in the transportation equipment.

For example, as illustrated in FIG. 2, mechanical relays 30 are disposed in the current path connecting the plus terminal of battery 200 to the plus terminal of load 400 and in the current path connecting the minus terminal of battery 200 to the minus terminal of load 400, respectively. For example, pyrofuse 20 is disposed in the current path to be closer to battery 200 than to mechanical relay 30.

For example, a high voltage of 100 V or more can be applied to mechanical relay 30, and mechanical relay 30 can be turned on and off repeatedly several tens of thousands times or more. For example, mechanical relay 30 is capable of continuously electrically conducting a current of 300 A or less, and can disconnect (turn on and off) the current path in which a current of 300 A or less flows, several times. For example, mechanical relay 30 is capable of disconnecting the current path in which a current of 2000 A or less flows under application of a voltage of 1000 V or less.

Mechanical relay 30 rather than a semiconductor relay is used in battery disconnect unit 100 because many semiconductor relays should be arranged in parallel to allow a semiconductor relay to function as a small current-carrying resistor like mechanical relay 30, which leads to demerits in cost and size.

To be noted, when mechanical relay 30 is turned on in activation of the transportation equipment, an inrush current unintentionally flows. Thus, battery disconnect unit 100 includes pre-charge relay 31 and pre-charge resistor 32 as inrush current measures. Pre-charge relay 31 is turned on and off by a signal from ECU 300.

Pre-charge relay 31 and pre-charge resistor 32 are connected in series, and a circuit in which pre-charge relay 31 and pre-charge resistor 32 are connected in series is connected to mechanical relay 30 in parallel. For example, when a vehicle is activated, mechanical relay 30 disposed in the current path close to the plus terminal is turned off, pre-charge relay 31 is turned on, and mechanical relay 30 disposed in the current path close to the minus terminal is turned on. Thereby, a current flows to load 400 via pre-charge resistor 32, and thus occurrence of an inrush current can be prevented. For example, the voltage of a smoothing capacitor included in load 400 becomes substantially equal to the voltage of battery 200 in about 0.3 s, mechanical relay 30 disposed in the current path close to the plus terminal is turned on, and the normal operation is started.

More preferably, pre-charge relay 31 is of the same type as that of mechanical relay 30. Pre-charge relay 31 can have the same configuration as that of mechanical relay 30. On the other hand, pre-charge relay 31 may be a relay of a semiconductor type.

Current sensor 40 is a sensor that detects the current value of the current flowing in the current path connecting battery 200 to load 400. For example, current sensor 40 is capable of continuously electrically conducting a current of 300 A or less. For example, current sensor 40 is a shunt-type sensor (such as a shunt resistor: for example, about 20 μΩ to about 80 μΩ). Current sensor 40 outputs the detected current value (analog value) to disconnection control circuit 10. Current sensor 40 may be a sensor such as a Hall element.

When a large current continues flowing in the current path, a failure may occur in pyrofuse 20, mechanical relay 30, or current sensor 40. For example, when a large current flows in the current path, mechanical relay 30 may explode.

Here, failure properties of mechanical relay 30 will be described. When a current of 500 A flows in the current path, a failure (e.g., explosion) does not occur until 100000 ms passes even if the current continues flowing in the current path. However, a failure of mechanical relay 30 occurs when the current continues flowing for 100000 ms or longer. For example, when a current of 6000 A larger than 500 A flows in the current path and the current continues flowing for 200 ms or longer, a failure of mechanical relay 30 occurs. Thus, when a small current flows in the current path, a failure of mechanical relay 30 is difficult to occur even if the current continues flowing for a long time. When a large current flows in the current path, a failure of mechanical relay 30 occurs when the current flows only for a short time. Thus, disconnection control circuit 10 determines based on the current value of the current flowing in the current path whether a current flowing in the current path is an overcurrent, outputs the ignition signal to pyrofuse 20, and causes pyrofuse 20 to disconnect the current path when the current flowing in the current path is an overcurrent.

Disconnection control circuit 10 is a circuit that disconnects the current path by driving pyrofuse 20. Disconnection control circuit 10 is implemented by a micro controller unit (MCU), for example. Disconnection control circuit 10 may be implemented by an application specific integrated circuit (ASIC), for example. Disconnection control circuit 10 includes current obtainer 11, disconnection determiner 12, and ignition controller 14. For example, current obtainer 11 and disconnection determiner 12 are implemented by micro controller unit 13, and ignition controller 14 is implemented by ASIC 15.

Current obtainer 11 is an AD converter that obtains the current value of the current flowing in the current path (analog value), which is detected by current sensor 40, and converts the current value to a digital value (referred to as AD value). Current obtainer 11 outputs the AD value to disconnection determiner 12. For example, current obtainer 11 converts the current value detected by current sensor 40 to an AD value at a constant time interval, and outputs the AD value to disconnection determiner 12.

Disconnection determiner 12 determinates whether the current flowing in the current path is an overcurrent. Specifically, disconnection determiner 12 determines whether to drive pyrofuse 20 (that is, to disconnect the current path), based on whether the current value detected by current sensor 40 (specifically, the AD value obtained from current obtainer 11) represents an overcurrent.

When disconnection determiner 12 determines that the current flowing in the current path is an overcurrent (that is, determines to drive pyrofuse 20), ignition controller 14 outputs an ignition signal for driving pyrofuse 20, to pyrofuse 20. This can disconnect the current path.

Disconnection determiner 12 can determine whether the current flowing in the current path is an overcurrent, by any method. To be noted, for the current flowing in the current path, noises should be distinguished from an overcurrent. Then, for example, disconnection determiner 12 may include a filter that removes noises. Alternatively, for example, disconnection determiner 12 may average current values detected by current sensor 40 during a certain period, and may determine whether the current flowing in the current path is an overcurrent, based on whether the average is greater than or equal to a predetermined value.

Thus, disconnection determiner 12 can determine whether the overcurrent is not temporary one caused by noises and is the one which continues flowing in the current path, and when the overcurrent continues flowing, can drive pyrofuse 20 through ignition controller 14 to disconnect the current path.

Once pyrofuse 20 is driven, the transportation equipment cannot be recovered unless pyrofuse 20 is exchanged. For this reason, it is very important to prevent pyrofuse 20 from being driven by mistake. Thus, battery disconnect unit 100 may include two current sensors 40. For example, current sensors 40 may be arranged in the current path to detect current values which are the same, and disconnection determiner 12 may detect a failure of current sensors 40 using two AD values. When the two AD values are different from each other, disconnection determiner 12 can determine that a failure occurs in at least one of two current sensors 40. Although the two AD values should be the same, two different AD values indicate that highly possibly a failure occurs in at least one of two current sensors 40. For example, when disconnection determiner 12 determines that a failure occurs in at least one of two current sensors 40, a user or administrator of the transportation equipment is notified of this, and current sensor 40 is repaired. Thereby, a failure of the device disposed in the current path, such as mechanical relay 30, can be prevented, and driving of pyrofuse 20 by mistake due to a failure of current sensor 40 can be prevented. In particular, when the overcurrent is determined using a time integrated value, a failure of the device disposed in the current path, such as mechanical relay 30, can be prevented, and driving of pyrofuse 20 by mistake due to a failure of current sensor 40 can be prevented.

Pyrofuse 20 has a demerit that once pyrofuse 20 is driven, the transportation equipment cannot be recovered unless pyrofuse 20 is exchanged. Mechanical relay 30 has a merit that it can be repeatedly turned on and off even after an anomaly is fixed or when any failure has not occurred. Then, a failure other than failures such as flowing of an overcurrent in the current path is detected by ECU 300, and mechanical relay 30 is turned on and off based on the result of failure detection.

Although the present invention is applicable to hybrid vehicles including an engine, for example, as the transportation equipment, preferably, the present disclosure is used in battery electric vehicles which need a battery of a larger capacity than that of batteries for hybrid vehicles.

As described above, in transportation equipment including battery 200 of a large capacity, such as electric vehicles, an extremely large current may flow in a current path connecting battery 200 and load 400 when an anomaly occurs. Since pyrofuse 20 can disconnect the current path when a large current of several tens of thousands ampere flows in the current path, the current path can be safely disconnected by battery disconnect unit 100 including pyrofuse 20. Since pyrofuse 20 and disconnection control circuit 10 that outputs an ignition signal to pyrofuse 20 are arranged in one rigid body portion 110, when disconnection control circuit 10 determines that the current flowing in the current path is an overcurrent, an ignition signal can be immediately transmitted to pyrofuse 20 from disconnection control circuit 10 disposed close to pyrofuse 20 in one rigid body portion 110. Accordingly, in the transportation equipment including battery 200 of a large capacity, the current path can be disconnected quickly and safely.

Since compared to semiconductor relays, mechanical relay 30 can enhance disconnection performance without increasing the size and cost, increases in size and cost of battery disconnect unit 100 can be suppressed in the transportation equipment including battery 200 of a large capacity in which a large current may flow. Since ECU 300 can detect failures in the transportation equipment, for a failure other than failures such as flowing of an overcurrent in the current path, the current path can be disconnected by turning off mechanical relay 30.

### Other Embodiments

As described above, the embodiment has been described as an example of the technique according to the present disclosure. However, the technique according to the present disclosure is not limited to this, and is appropriately applicable to embodiments subjected to changes, replacements, additions, omissions, or the like. For example, one embodiment according to the present disclosure also covers modifications below.

The components included in disconnection control circuit 10 according to the embodiment may be implemented as dedicated or general-purpose circuits.

Alternatively, the components included in disconnection control circuit 10 according to the embodiment may be implemented as large scale integration (LSI), which is an integrated circuit (IC).

The integrated circuit is not limited to LSI, and may be implemented as a dedicated circuit or a general-purpose processor. A programmable field programmable gate array (FPGA) or a reconfigurable processor enabling reconfiguration of connection and setting of circuit cells inside the LSI may be used.

Furthermore, if a technique of forming an integrated circuit replacing LSI will appear as a result of progression of semiconductor techniques or derivation of another technique, it is natural to form the components included in disconnection control circuit 10 into an integrated circuit using such a technique.

Besides, the present disclosure also covers embodiments obtained by performing a variety of modifications conceived by persons skilled in the art on the embodiment and those implemented by any combination of components and functions in the embodiments without departing from the gist of the present disclosure.

### Appendix

According to the above-mentioned embodiments, the following techniques will be disclosed.

(Technique 1) A battery disconnect unit for use in transportation equipment including a battery and a load, the battery disconnect unit including: a pyrofuse; a mechanical relay including a first contact and a second contact; a current sensor; and a disconnection control circuit connected to the current sensor and the pyrofuse, wherein the current sensor outputs, to the disconnection control circuit, a current value of a current flowing in a current path between the battery and the load, the disconnection control circuit outputs an ignition signal to the pyrofuse based on the current value, the pyrofuse disconnects the current path by the ignition signal, and the mechanical relay is turned on and off by a control signal from outside of the battery disconnect unit.

In transportation equipment including a battery of a large capacity, such as electric vehicles, a large current may flow in a current path connecting the battery to the load when an anomaly occurs. Since the pyrofuse can disconnect the current path even when a large current of several tens of thousands ampere flows in the current path, the current path can be disconnected safely by the battery disconnect unit including the profuse. Accordingly, in the transportation equipment including a battery of a large capacity, the current path can be disconnected safely.

Since compared to semiconductor relays, the mechanical relay can enhance disconnection performance without increasing the size and cost, increases in size and cost of the battery disconnect unit can be prevented in the transportation equipment including a battery of a large capacity in which a large current may flow.

When an anomaly occurs in the transportation equipment, the current path can be disconnected by turning off the mechanical relay by the control signal from an electronic control unit disposed outside the battery disconnect unit.

(Technique 2) The battery disconnect unit according to technique 1, in which the disconnection control circuit recognizes occurrence of arc discharge in the mechanical relay, based on a change in the current value from the current sensor, and outputs the ignition signal to the pyrofuse.

Thus, because the disconnection control circuit can recognize occurrence of arc discharge in the mechanical relay by monitoring the change in the current value, the disconnection control circuit can output the ignition signal to the pyrofuse based on the change in the current value from current sensor 4.

(Technique 3) The battery disconnect unit according to technique 1 or 2, in which the disconnection control circuit: stores a first time period that is from the output of the ignition signal to the occurrence of arc discharge in the pyrofuse; predicts a time when the current value of the current flowing in the current path exceeds a threshold current, using the first time period and a plurality of current values that are measured at different measurement times and input from the current sensor; and outputs the ignition signal to the pyrofuse based on the prediction, to cause arc discharge to occur in the mechanical relay and then in the pyrofuse and to cause a period during which arc discharge occurs in the mechanical relay and a period during which arc discharge occurs in the pyrofuse to overlap with each other.

Thus, the current path may be disconnected based on the prediction when the current value of the current flowing in the current path exceeds the threshold current.

(Technique 4) The battery disconnect unit according to any one of techniques 1 to 3, in which when a current exceeding a threshold current flows in the current path, after the first contact is spaced from the second contact and arc discharge occurs, the disconnection control circuit outputs the ignition signal to the pyrofuse to disconnect the load and the battery, and the arc discharge occurs both between the first contact and the second contact and in a portion of the current path decoupled by the pyrofuse.

Thus, in the battery disconnect unit, after disconnection between the load and the battery is performed by outputting the ignition signal to the pyrofuse, arc discharge occurs in the mechanical relay and the pyrofuse. (Technique 5) The battery disconnect unit according to any one of techniques 1 to 4, in which the transportation equipment includes an electronic control unit that is disposed outside the battery disconnect unit, is connected to the battery and the load without being connected to the current sensor, and outputs the control signal, and the mechanical relay is turned on and off by the control signal based on information from the battery or the load.

Since the electronic control unit disposed outside the battery disconnect unit can monitor an anomaly of the battery or the load in the transportation equipment, the current path can be disconnected by turning off the mechanical relay when an anomaly occurs in the battery or the load.

(Technique 6) The battery disconnect unit according to technique 5, in which the control signal is a signal generated based on a result of failure detection in the transportation equipment.

The electronic control unit generates the control signal based on the result of failure detection in the transportation equipment, and outputs the control signal to the mechanical relay. Thereby, the mechanical relay can be turned on and off according to the result of failure detection in the transportation equipment.

(Technique 7) The battery disconnect unit according to any one of techniques 1 to 6, in which the pyrofuse: is configured to continuously electrically conduct a current of 500 A or less; and is configured to disconnect the current path in which a current of 25000 A or less flows under application of a voltage of 1000 V or less.

Since the pyrofuse has such performance, the current path can be disconnected even when a large current of several tens of thousands ampere flows in the current path.

(Technique 8) The battery disconnect unit according to any one of techniques 1 to 7, in which the mechanical relay: is configured to continuously electrically conduct a current of 300 A or less; and is configured to disconnect the current path in which a current of 2000 A or less flows under application of a voltage of 1000 V or less.

Since the mechanical relay has such performance, the current path can be repeatedly turned on and off in the transportation equipment including a battery of a large capacity.

(Technique 9) The battery disconnect unit according to any one of techniques 1 to 8, in which the current sensor is configured to continuously electrically conduct a current of 300 A or less.

Since the current sensor has such performance, the current flowing in the current path can be detected in the transportation equipment including a battery of a large capacity.

(Technique 10) The battery disconnect unit according to any one of techniques 1 to 9, including two current sensors each of which is the current sensor, in which the disconnection control circuit detects a failure in at least the two current sensors based on the current value of each of the two current sensors.

The two current sensors are arranged in the current path to detect current values which are the same. For this reason, when the two current values are different, it can be determined that a failure occurs at least one of the two current sensors.

(Technique 11) The battery disconnect unit according to any one of techniques 1 to 10, in which the pyrofuse is disposed in the current path to be closer to the battery than to the mechanical relay.

Thereby, the current path can be disconnected in a position closer to the battery by the pyrofuse, enhancing safety.

(Technique 12) The battery disconnect unit according to any one of techniques 1 to 11, in which the current sensor is a shunt-type sensor.

The shunt-type current sensor can detect a large current. For this reason, even when a large current flows in the current path in the transportation equipment including a battery of a large capacity, the current flowing in the current path can be detected by the shunt-type current sensor.

(Technique 13) The battery disconnect unit according to any one of techniques 1 to 12, in which the disconnection control circuit includes a current obtainer, a disconnection determiner, and an ignition controller, the current obtainer obtains the current value of the current flowing in the current path, the disconnection determiner determines whether the current flowing in the current path is an overcurrent, and the ignition controller outputs the ignition signal to the pyrofuse when disconnection determiner determines that the current flowing in the current path is an overcurrent.

Thus, the disconnection control circuit can be implemented by the current obtainer, the disconnection determiner, and the ignition controller.

### INDUSTRIAL APPLICABILITY

The present disclosure is applicable to systems that disconnect current paths by driving pyrofuses.

### REFERENCE SIGNS LIST

10 disconnection control circuit
11 current obtainer
12 disconnection determiner
13 micro controller unit
14 ignition controller
20 pyrofuse
30 mechanical relay
31 pre-charge relay
32 pre-charge resistor
40 current sensor
100 battery disconnect unit
110 rigid body portion
120 cover
200 battery
201 casing
202 igniter
203 piston
204 busbar
300 ECU
301 first circuit portion
302 second circuit portion
303 movable terminal
304 fixed terminal
305 contact (first contact)
306 contact (second contact)
307 movable portion
400 load

1. A battery disconnect unit for use in transportation equipment including a battery and a load, the battery disconnect unit comprising:
a pyrofuse;
a mechanical relay including a first contact and a second contact;
a current sensor; and
a disconnection control circuit connected to the current sensor and the pyrofuse,
wherein the current sensor outputs, to the disconnection control circuit, a current value of a current flowing in a current path between the battery and the load,
the disconnection control circuit outputs an ignition signal to the pyrofuse based on the current value,
the pyrofuse disconnects the current path by the ignition signal, and
the mechanical relay is turned on and off by a control signal from outside of the battery disconnect unit.

2. The battery disconnect unit according to claim 1,
wherein the disconnection control circuit recognizes occurrence of arc discharge in the mechanical relay, based on a change in the current value from the current sensor, and outputs the ignition signal to the pyrofuse.

3. The battery disconnect unit according to claim 1,
wherein the disconnection control circuit:
stores a first time period that is from the output of the ignition signal to the occurrence of arc discharge in the pyrofuse;
predicts a time when the current value of the current flowing in the current path exceeds a threshold current, using the first time period and a plurality of current values that are measured at different measurement times and input from the current sensor; and
outputs the ignition signal to the pyrofuse based on the prediction, to cause arc discharge to occur in the mechanical relay and then in the pyrofuse and to cause a period during which arc discharge occurs in the mechanical relay and a period during which arc discharge occurs in the pyrofuse to overlap with each other.

4. The battery disconnect unit according to claim 1,
wherein when a current exceeding a threshold current flows in the current path, after the first contact is spaced from the second contact and arc discharge occurs, the disconnection control circuit outputs the ignition signal to the pyrofuse to disconnect the load and the battery, and the arc discharge occurs both between the first contact and the second contact and in a portion of the current path decoupled by the pyrofuse.

5. The battery disconnect unit according to claim 1,
wherein the transportation equipment includes an electronic control unit that is disposed outside the battery disconnect unit, is connected to the battery and the load without being connected to the current sensor, and outputs the control signal, and
the mechanical relay is turned on and off by the control signal based on information from the battery or the load.

6. The battery disconnect unit according to claim 5,
wherein the control signal is a signal generated based on a result of failure detection in the transportation equipment.

7. The battery disconnect unit according to claim 1,
wherein the pyrofuse:
is configured to continuously electrically conduct a current of 500 A or less; and
is configured to disconnect the current path in which a current of 25000 A or less flows under application of a voltage of 1000 V or less.

8. The battery disconnect unit according to claim 1,
wherein the mechanical relay:
is configured to continuously electrically conduct a current of 300 A or less; and
is configured to disconnect the current path in which a current of 2000 A or less flows under application of a voltage of 1000 V or less.

9. The battery disconnect unit according to claim 1,
wherein the current sensor is configured to continuously electrically conduct a current of 300 A or less.

10. The battery disconnect unit according to claim 1, comprising two current sensors each of which is the current sensor,
wherein the disconnection control circuit detects a failure in at least the two current sensors based on the current value of each of the two current sensors.

11. The battery disconnect unit according to claim 1,
wherein the pyrofuse is disposed in the current path to be closer to the battery than to the mechanical relay.

12. The battery disconnect unit according to claim 1,
wherein the current sensor is a shunt-type sensor.

13. The battery disconnect unit according to claim 1,
wherein the disconnection control circuit includes a current obtainer, a disconnection determiner, and an ignition controller,
the current obtainer obtains the current value of the current flowing in the current path,
the disconnection determiner determines whether the current flowing in the current path is an overcurrent, and
the ignition controller outputs the ignition signal to the pyrofuse when disconnection determiner determines that the current flowing in the current path is an overcurrent.
